(19) United States
(12) Patent Application Publication
(10) Pub. No.: US 2010/0006920 A1
(43) Pub. Date: Jan. 14, 2010

(54) SEMICONDUCTOR MEMORY DEVICE AND MANUFACTURING METHOD THEREOF

(75) Inventors: Nobutoshi Aoki, Yokohama-Shi (JP); Masaki Kondo, Kawasaki-Shi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: Kabushiki Kaisha Toshiba, Tokyo (JP)

(21) Appl. No.: 12/486,985

(22) Filed: Jun. 18, 2009

(30) Foreign Application Priority Data
Jul. 14, 2008 (JP) 2008-182475

(51) Int. Cl. H01L 29/788; H01L 21/762

(52) U.S. Cl. 257/321; 438/424; 257/E29.304; 257/E21.546

(57) ABSTRACT

A semiconductor memory device according to an embodiment may include a plurality of memory cells arranged on a semiconductor substrate includes a tunneling dielectric film on the semiconductor substrate; a floating gate formed on the tunneling dielectric film and corresponding to each of the memory cells; an inter-gate dielectric film on the floating gate; and a control gate on the inter-gate dielectric film, wherein the floating gate corresponding to a single memory cell has a first gate part, a second gate part, and the floating gate has a part that the tunneling dielectric film contacts the inter-gate dielectric film is provided between the first gate part and the second gate part within the memory cell.

### CROSS-REFERENCE TO RELATED APPLICATION

This application is based upon and claims the benefit of priority from the prior Japanese Patent Applications No. 2008-182475, filed on Jul. 14, 2008, the entire contents of which are incorporated herein by reference.

### BACKGROUND

In non-volatile memories like flash memories, a coupling capacitance between a control gate (hereinafter, also CG) and a floating gate (hereinafter, also FG) is increased, so that the CG can control an electrical potential of the FG efficiently. To increase the coupling capacitance between the CG and the FG, the opposing area of the FG to the CG is probably increased.

To increase the opposing area of an FG to a CG, an STI (Shallow Trench Isolation) or the FG has been conventionally processed so that the CG faces not only a surface of the FG but also a side surface thereof.

For example, a central part of an STI between two adjacent FGs is made low and a CG is buried between the adjacent FGs (S. Aritome, “Advanced Flash Memory Technology and Trends for File Storage Application” IEDM2000T (prior example 1)). Alternatively, a central part of the FG is made low (or ends of the FG are protruded) and the CG is buried in the central part of the FG (Kitamura et al., “A Low Voltage Operating Flash Memory Cell with High Coupling Ratio Using Horned Floating Gate with Fine HSG” VSLI symposium 1998, and Japanese Patent Laid-open No. 2002-118186 (prior example 2)).

As a cell size and the STI's width are reduced according to memories' high integration, burying the CG by lithography disclosed in prior example 1 is difficult. Further, forming an inter-gate dielectric film (hereinafter, also IPD (Inter-Poly-Si Dielectric) film) between the CG and the FG disclosed in prior example 2 is also difficult.

According to prior example 2, as memories' downscaling progresses, a part on an IPD film that a CG is buried is formed in a protruded shape. An electric field concentrates on the protrusion, so that the IPD film in the vicinity of a distal end of the protrusion may cause dielectric breakdown. If the electric field concentrates on the protrusion, electrons may be implanted from the protrusion (buried part) of the CG via the IPD film in the FG by tunneling at the time of data erase. This causes inferior erase. The protrusion at the ends of the FG may increase the opposing area of two adjacent FGs. If the width of an STI is reduced and the opposing area of adjacent FGs is increased, the coupling capacitance between adjacent memory cells is increased and interference between the memory cells caused by proximity effect is increased.

### SUMMARY

A semiconductor memory device according to an embodiment may include a plurality of memory cells arranged on a semiconductor substrate comprises: a tunneling dielectric film on the semiconductor substrate; a floating gate formed on the tunneling dielectric film and corresponding to each of the memory cells; an inter-gate dielectric film on the floating gate; and a control gate on the inter-gate dielectric film, wherein the floating gate corresponding to a single memory cell has a first gate part, a second gate part, and the floating gate has a part that the tunneling dielectric film contacts the inter-gate dielectric film is provided between the first gate part and the second gate part within the memory cell.

A manufacturing method of a semiconductor memory device according to an embodiment may include a plurality of memory cells arranged on a semiconductor substrate, the semiconductor memory device comprising: a tunneling dielectric film on the semiconductor substrate; a floating gate on the tunneling dielectric film; an inter-gate dielectric film on the floating gate; and a control gate on the inter-gate dielectric film, the method comprises: forming a dummy gate material above the semiconductor substrate; removing the dummy gate material and a part of the semiconductor substrate in the region where isolations separating the memory cells are to be formed; filling an insulation material in a region of the isolations to form the isolations; removing the dummy gate material; depositing a material for the floating gate on top and side surfaces of the isolation; anisotropically etching the material for the floating gate in such a manner that the top surface of the tunneling dielectric film is exposed at the central part of the memory cell, in order for the floating gate corresponding the single memory cell to remain along the side surface of the isolation; forming the inter-gate dielectric film on the floating gate; and forming the control gate on the inter-gate dielectric film.

### BRIEF DESCRIPTION OF THE DRAWINGS

FIG. 1 is a plan view showing an example of configuration of a NAND flash memory according to a first embodiment;

FIG. 2 is a cross-sectional view along a line 2-2 shown in FIG. 1;

FIGS. 3A to 3C and FIGS. 4A to 4C are cross-sectional views showing a manufacturing method of a memory according to the first embodiment;

FIG. 5 is a cross-sectional view showing a configuration of a memory cell according to a second embodiment; and

FIGS. 6A and 6B are cross-sectional views showing a manufacturing method of a memory according to the second embodiment.

### DETAILED DESCRIPTION OF THE INVENTION

Embodiments of the present invention will be explained below in detail with reference to the accompanying drawings. Note that the invention is not limited thereto.

### First Embodiment

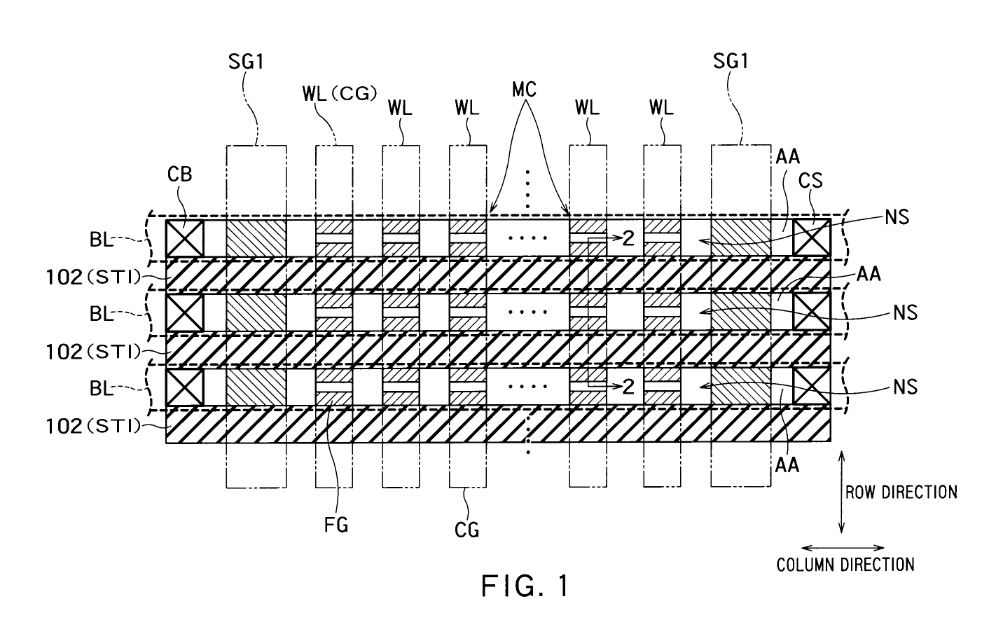

FIG. 1 is a plan view showing an example of configuration of a NAND flash memory (hereinafter, simply “memory”) according to a first embodiment. The embodiment can be applied to, in addition to NAND flash memories, memories with floating gates. The NAND flash memory according to the first embodiment is applied to, e.g., products in the generation that a minimum line width is about 30 nm or in the generation that a minimum line width is about 20 nm or less, but is not limited especially thereto. Although prior examples 1 and 2 tend to be influenced by the above-described problems in these generations, the first embodiment can solve the problems. It is thus effective to employ the first embodiment in the generations.

The memory according to the first embodiment includes word lines WL extending in a row direction and bit lines BL extending in a column direction. The word line WL crosses the bit line BL to be orthogonal to the same. A memory cell MC is provided at intersections of the word lines WL with the bit lines BL. The word line WL also serves as a control gate CG. Thus, the word line WL is also called hereinafter the control gate CG.

The memory cell MC is formed in an active area AA extending in the column direction. The active area AA and an STI 102 serving as isolation extend in the column direction. The active area AA and the STI 102 are arranged alternatively in the row direction in stripes.

The NAND flash memory includes NAND strings NS each of which is formed of a plurality of memory cells MC serially connected together in the column direction. While three NAND strings NS are shown in FIG. 1, a large number of NAND strings are usually provided. Each NAND string NS is connected via a selective gate SG1 to the bit line BL and via a selective gate SG2 to the source.

Because the column direction and the row direction are determined for convenience, they are interchangeable.

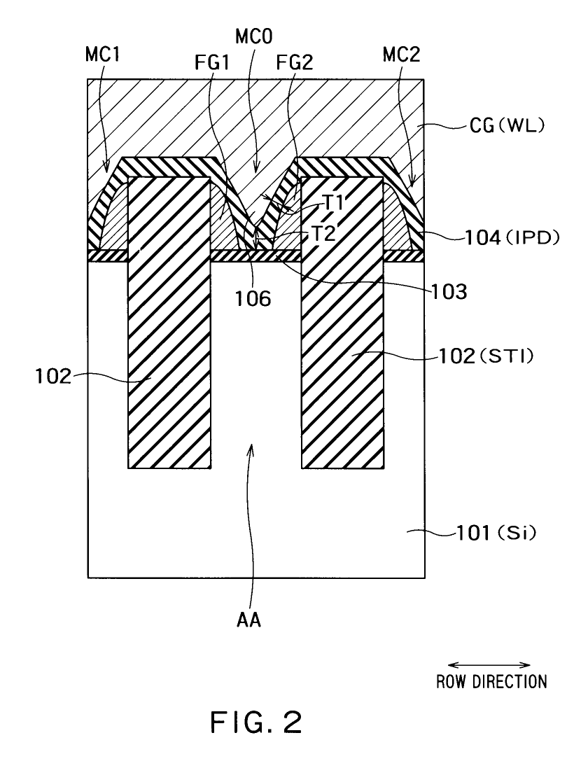

FIG. 2 is a cross-sectional view along a line 2-2 shown in FIG. 1. The memory cell MC is formed in the active area AA between two adjacent STIs 102. Each memory cell MCi (i is integer) includes a tunneling dielectric film 103 on a silicon substrate 101, floating gates FG1 and FG2 on the tunneling dielectric film 103, and an IPD 104 serving as an inter-gate dielectric film on the floating gates FG1 and FG2. The control gate CG (word line WL) is provided on the IPD 104.

According to the prior examples, one floating gate is provided for every memory cell MCi. In the first embodiment, however, the floating gate is provided for every memory cell MCi but divided into two in the row direction (FG1 and FG2). Namely, a floating gate corresponding to a single memory cell MCi is divided into a first gate part FG1 and a second gate part FG2 in a vertical direction. The IPD film 104 thus contacts the tunneling dielectric film 103 between the floating gate FG1 and the floating gate FG2.

The first gate part FG1 is provided at a corner between the tunneling dielectric film 103 and a side surface of one of two STIs 102 adjacent to each other in the row direction. Namely, the first gate part FG1 faces the side surface of one STI 102 and a surface of the tunneling dielectric film 103.

The second gate part FG2 is provided at a corner between the tunneling dielectric film 103 and the side surface of the other of two STIs 102 adjacent to each other in the row direction. Namely, the second gate part FG2 faces the side surface of the other STI 102 and the surface of the tunneling dielectric film 103.

The first gate part FG1 and the second gate part FG2 are electrically separated from each other by the IPD 104 at the row direction intermediate part of the memory cell MCi. When the floating gate is depressed at the row direction intermediate part of the memory cell MC as described above, the control gate CG can have a protrusion 106 toward the silicon substrate 101 so as to correspond to the depression of the floating gate.

Because the control gate CG has the protrusion 106, the opposing area of the control gate CG to the floating gates FG1 and FG2 can be increased. A floating gate-control gate capacitance coupling ratio Cr (Cr=Cipd/(Cipd+Cfg)) is increased. Cipd indicates a floating gate-control gate capacitance with the IPD 104 interposed therebetween. Cfg indicates a floating gate-silicon substrate capacitance with the tunneling dielectric film 103 interposed therebetween.

In the first embodiment, the first gate part FG1 and the second gate part FG2 are isolated from each other while corresponding to the single memory cell MCi. Influences of proximity effect caused by other memory cell MCi−1 or MCi+1 adjacent to the memory cell MCi in the row direction are thus reduced. For example, the proximity effect exerted from the memory cell MC1 adjacent to the memory cell MC0 on the first gate part FG1 side upon the memory cell MC0 almost affects only the first gate part FG1. This is because the second gate part FG2 is apart from the memory cell MC1 and separated from the first gate part FG1.

The proximity effect exerted from the memory cell MC2 adjacent to the memory cell MC0 on the second gate part FG2 side upon the memory cell MC0 almost affects only the second gate part FG2. This is because the first gate part FG1 is apart from the memory cell MC2 and separated from the second gate part FG2.

According to the first embodiment, the influences of the proximity effect can be reduced substantially by half by dividing the floating gate into multiple parts. Accordingly, the proximity effect can be suppressed even if the width of the STI 102 is made narrow in the first embodiment.

In the proximity effect, electrical characteristics of a memory cell of interest (such as threshold voltage) are influenced by the data status of other memory cells adjacent to the memory cell of interest to be varied.

Because the first gate part FG1 is separated from the second gate part FG2, the opposing area of floating gates of a plurality of memory cells adjacent to each other in the column direction is reduced. For example, the intermediate part of the floating gate is removed and depressed. The cross-sections of the first and second gate parts FG1 and FG2 shown in FIG. 2 are reduced and the opposing area of the floating gates adjacent to each other in the column direction is thus reduced. As a result, the proximity effect between the memory cells adjacent to each other in the column direction is weakened.

In the first embodiment, the thickness T2 of the IPD 104 between the protrusion 106 of the control gate CG and the silicon substrate 101 is larger than one T1 of the IPD 104 between the floating gates FG1 and FG2 and the control gate CG. Thus, even if the control gate CG has the protrusion 106 toward the silicon substrate 101, a dielectric breakdown of the IPD 104 can be suppressed between the control gate CG and the silicon substrate 101.

The protrusion 106 extends toward the silicon substrate 101 above the silicon substrate 101. Most of electric charges are thus tunneled toward not the floating gate FG but the silicon substrate 101. Tunneling of electric charges from the control gate CG to the floating gates FG1 and FG2 is suppressed, which results in suppression of inferior data erase caused by the tunneling of electric charges.

The separated first and second gate parts FG1 and FG2 of the first embodiment are made by not lithography but anisotropic etching in a self-aligned manner. The first embodiment is thus suitable for downscaling of memory cells MC.

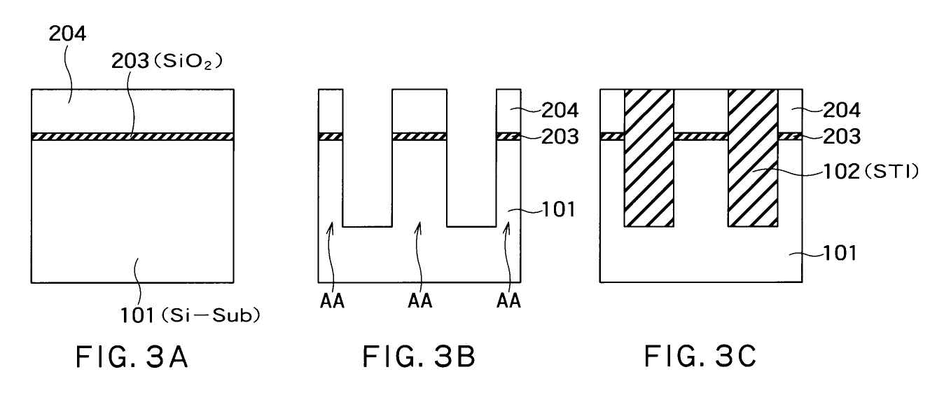

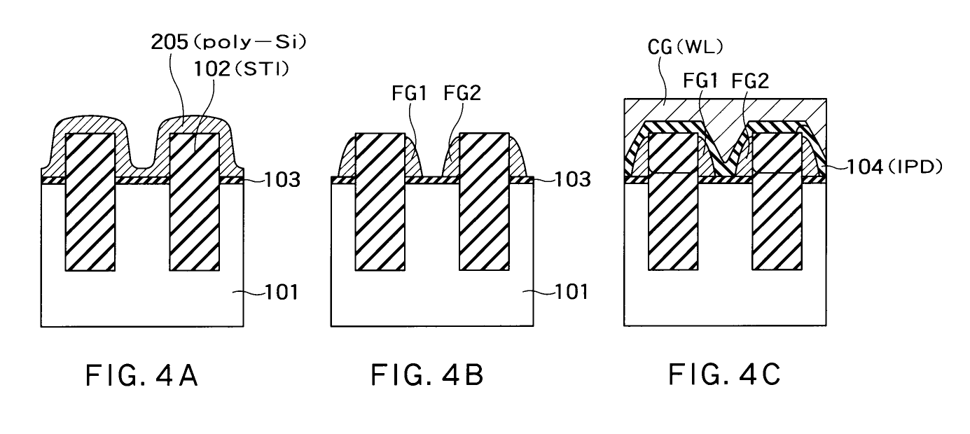

FIGS. 3A to 3C and FIGS. 4A to 4C are cross-sectional views showing a manufacturing method of a memory according to the first embodiment. As shown in FIG. 3A, an insulation film 203 is first formed on a surface of the silicon substrate 101. A dummy gate 204 is deposited on the insulation film 203. The insulation film 203 is made of, e.g., a silicon oxide film. When the insulation film 203 is used as the tunneling dielectric film 103, the insulation film 203 can be made of, in addition to the silicon oxide film, high dielectric materials with higher relative dielectric constant than the silicon oxide film. The dummy gate 204 is made of, e.g., a silicon nitride film. The dummy gate 204 can be made of any materials as long as they have larger selectivity than materials for the insulation film 203 and the STI 102.

As shown in FIG. 3B, the dummy gate 204, the insulation film 203, and the silicon substrate 101 in the region where STI is to be formed are then removed by lithography and RIE (Reactive Ion Etching). Consequently, the active area AA is determined.

As shown in FIG. 3C, an insulation film is buried in the region where STI is to be formed. At this time, a surface of the insulation film is flattened by CMP (Chemical-Mechanical Polish). The STI 102 is thus formed.

As shown in FIG. 4A, the dummy gate 204 is removed. When the insulation film 203 is used as the tunneling dielectric film 103, it remains as the tunneling dielectric film 103. When the insulation film 203 is not used as the tunneling dielectric film 103, the insulation film 203 is removed temporarily and then the tunneling dielectric film 103 is newly formed.

Further, a polysilicon film 205 serving as a material for the floating gates FG1 and FG2 is deposited on top and side surfaces of the STI 102 and on the tunneling dielectric film 103.

The polysilicon film 205 is anisotropically etched by RIE. As shown in FIG. 4B, the first gate part FG1 and the second gate part FG2 are formed so as to be separated from each other on the side surface of the STI 102 and on the tunneling dielectric film 103. The first gate part FG1 and the second gate part FG2 are divided at the central part of the memory cell MC in the row direction cross-section. At this time, the top surface of the tunneling dielectric film 103 is exposed between the floating gate FG1 and the floating gate FG2. As described above, the first gate part FG1 and the second gate part FG2 are formed in a self-aligned manner along the side surface of the STI 102 without utilizing lithography, like sidewalls or spacers. Thus, the memory according to the first embodiment has an excellent downscaling characteristic.

For impurity implantation in the first gate part FG1 and the second gate part FG2, phosphorous can be doped during deposition of the polysilicon film 205. Alternatively, after the polysilicon film 205 is deposited, an impurity can be ion-implanted in the polysilicon film 205. After the polysilicon film 205 is etched, distal ends of the first gate part FG1 and second gate part FG2 are rounded by oxidation process or isotropic etching such as CDE (Chemical Dry Etching). When sharp distal ends of the first gate part FG1 and the second gate part FG2 do not become a problem, however, their distal ends need not to be rounded.

As shown in FIG. 4C, the IPD film 104 is then deposited on the first gate part FG1 and the second gate part FG2. A polysilicon film is further deposited on the IPD film 104 as a material for the control gate CG. Because the top surface of the tunneling dielectric film 103 is exposed, the IPD film 104 contacts the tunneling dielectric film 103 between the floating gate FG1 and the floating gate FG2. The polysilicon film is patterned, so that the control gate CG is formed.

Contacts and wirings (such as bit lines) are then formed. According to the first embodiment, one of the floating gate and the control gate or both of them can be made of metals.

### Second Embodiment

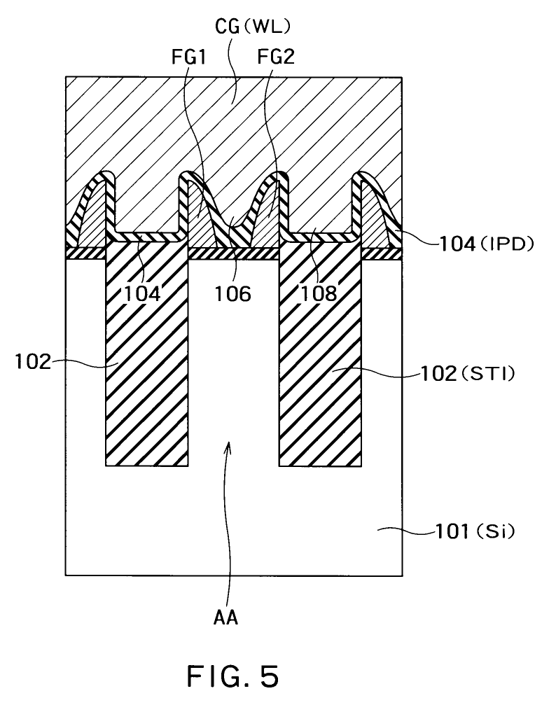

FIG. 5 is a cross-sectional view showing a configuration of a memory cell according to a second embodiment. The plan view of the second embodiment is substantially the same as the plan view shown in FIG. 1.

According to the second embodiment, the control gate CG has a protrusion 108 toward the silicon substrate 101 in the STI 102. Namely, the control gate CG has the protrusion 108 in the isolation region (STI region) as well as the protrusion 106 in the active area AA.

More specifically, the top surface of the STI 102 is placed closer to the silicon substrate 101 than the top surfaces (tops) of the floating gates FG1 and FG2. Namely, the STI 102 is depressed with respect to the floating gates FG1 and FG2, and the control gate CG is loaded in the depression.

The IPD 104 is provided between the protrusion 108 and the floating gates FG1, FG2 and between the protrusion 108 and the STI 102. Other configurations of the second embodiment can be the same as those of the first embodiment.

The control gate CG faces the side surfaces of the floating gates FG1 and FG2 not only in the active area AA but also in the STI 102 in the second embodiment. The floating gate-control gate capacitance coupling ratio Cr is thus further increased.

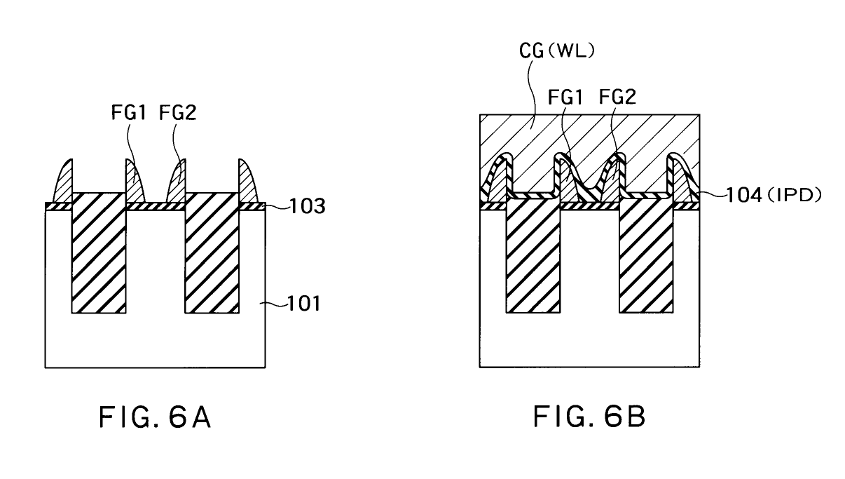

FIGS. 6A and 6B are cross-sectional views showing a manufacturing method of a memory according to the second embodiment. After the processes described with reference to FIGS. 3A to 3C and FIG. 4A are performed, as shown in FIG. 6A, the STI 102 is etched back to a height of midway of the floating gates FG1 and FG2. According to the second embodiment, only the central part of the STI is not removed by lithography unlike prior example 1. Instead, the entire top of the STI 102 is etched back. The second embodiment is thus suitable for downscaling of memory cells.

As shown in FIG. 6B, the IPD 104 is deposited on the top and side surfaces of the floating gates FG1 and FG2 and on the top surface of the STI 102. A material for the control gate CG (polysilicon) is deposited on the IPD 104. At this time, the protrusions 106 and 108 are formed simultaneously in a self-aligned manner. The material for the control gate CG is then patterned, so that the control gate CG is formed. Other manufacturing processes in the second embodiment are the same as those in the first embodiment.

As described above, according to the manufacturing method of the second embodiment, the floating gates FG1 and FG2 and the protrusions 106 and 108 are formed in a self-aligned manner without utilizing lithography. Thus, the memory according to the second embodiment has an excellent downscaling characteristic. Further, the second embodiment has the same effects as those of the first embodiment.

Embodiments of the invention have been described with reference to the examples. However, the invention is not limited thereto. Other embodiments of the present invention will be apparent to those skilled in the art from consideration of the specification and practice of the invention disclosed herein. It is intended that the specification and example embodiments be considered as exemplary only, with a true scope and spirit of the invention being indicated by the following.

1. A semiconductor memory device comprising a plurality of memory cells arranged on a semiconductor substrate comprising:
a tunneling dielectric film on the semiconductor substrate;
a floating gate formed on the tunneling dielectric film and corresponding to each of the memory cells;
an inter-gate dielectric film on the floating gate; and
a control gate on the inter-gate dielectric film, wherein the floating gate corresponding to a single memory cell has a first gate part, a second gate part, and
the floating gate has a part that the tunneling dielectric film contacts the inter-gate dielectric film, and the part is provided between the first gate part and the second gate part within the memory cell.

2. The device of claim 1, wherein
the memory cells are provided at intersections of word lines and bit lines crossing to each other, and
the floating gate is divided vertically at the intermediate part of the memory cell in a direction that the word line extends.

3. The device of claim 2, wherein the first gate part is separated from the second gate part by the inter-gate dielectric film.

4. The device of claim 2, wherein the control gate comprises a protrusion toward the semiconductor substrate at the intermediate part of the memory cell in the direction that the word line extends.

5. The device of claim 3, wherein the control gate comprises a protrusion toward the semiconductor substrate at the intermediate part of the memory cell in the direction that the word line extends.

6. The device of claim 4, wherein a thickness of the inter-gate dielectric film between the protrusion of the control gate and the semiconductor substrate is larger than a thickness between the floating gate and the control gate.

7. The device of claim 5, wherein a thickness of the inter-gate dielectric film between the protrusion of the control gate and the semiconductor substrate is larger than a thickness between the floating gate and the control gate.

8. The device of claim 1 further comprising isolations separating the memory cells, wherein
the first and second gate parts respectively face side surfaces of adjacent isolations.

9. The device of claim 2 further comprising isolations separating the memory cells, wherein
the first and second gate parts respectively face side surfaces of adjacent isolations.

10. The device of claim 1 further comprising isolations separating the memory cells, wherein
a top surface of the isolation is closer to the semiconductor substrate than a top surface of the floating gate, and
the control gate protrudes toward the semiconductor substrate in regions of the isolations.

11. The device of claim 2 further comprising isolations separating the memory cells, wherein
a top surface of the isolation is closer to the semiconductor substrate than a top surface of the floating gate, and
the control gate protrudes toward the semiconductor substrate in regions of the isolations.

12. The device of claim 4 further comprising isolations separating the memory cells, wherein
a top surface of the isolation is closer to the semiconductor substrate than a top surface of the floating gate, and
the control gate protrudes toward the semiconductor substrate in regions of the isolations.

13. A manufacturing method of a semiconductor memory device comprising a plurality of memory cells arranged on a semiconductor substrate, the semiconductor memory device including:
a tunneling dielectric film on the semiconductor substrate;
a floating gate on the tunneling dielectric film;
an inter-gate dielectric film on the floating gate; and
a control gate on the inter-gate dielectric film,
the method comprising:
forming a dummy gate material above the semiconductor substrate;
removing a part of the dummy gate material and a part of the semiconductor substrate in the region where isolations separating the memory cells are to be formed;
filling an insulation material in a region of the isolations to form the isolations;
removing the dummy gate material;
depositing a material for the floating gate on top and side surfaces of the isolation;
anisotropically etching the material for the floating gate in such a manner that the top surface of the tunneling dielectric film is exposed at the central part of the memory cell, in order for the floating gate corresponding the single memory cell to remain along the side surface of the isolation;
forming the inter-gate dielectric film on the floating gate; and
forming the control gate on the inter-gate dielectric film.

14. The method of claim 13 further comprising:
after etching the material for the floating gate, etching the isolations to a level lower than the top end of the floating gate, wherein
the material for the floating gate is deposited.

15. The method of claim 13 further comprising:
forming a tunneling dielectric film on the semiconductor substrate; and
depositing a dummy gate material on the tunneling dielectric film.
